(19) United States
(12) Patent Application Publication
(10) Pub. No.: US 2014/0048845 A1
(43) Pub. Date: Feb. 20, 2014

(54) SEMICONDUCTOR DEVICE AND METHOD FOR MANUFACTURING THE SAME

(71) Applicant: SAMSUNG ELECTRO-MECHANICS CO., LTD., Gyunggi-do (KR)

(72) Inventors: Dong Soo Seo, Gyunggi-do (KR); In Hyuk Song, Gyunggi-do (KR); Jae Hoon Park, Gyunggi-do (KR)

(73) Assignee: SAMSUNG ELECTRO-MECHANICS CO., LTD., Gyunggi-do (KR)

(21) Appl. No.: 13/707,582

(22) Filed: Dec. 6, 2012

(30) Foreign Application Priority Data
Aug. 17, 2012 (KR) 10-2012-0089963

(51) Int. Cl. H01L 29/78; H01L 29/66

(52) U.S. Cl. CPC H01L 29/7827; H01L 29/66325
USPC 257/139; 438/138

(57) ABSTRACT

Disclosed herein are a semiconductor device and a method for manufacturing the same, the semiconductor device including: trench gate electrodes formed in a semiconductor substrate; a gate insulating film covering an upper surface of the semiconductor substrate and lateral surfaces and lower surfaces of the trench gate electrodes; a base region formed between the trench gate electrodes; an emitter region formed between the trench gate electrodes and on the base region; interlayer insulating films formed on the trench gate electrodes and spaced apart from each other; an emitter metal layer formed on the interlayer insulating films and between the interlayer insulating films.

### CROSS REFERENCE TO RELATED APPLICATION

This application claims the benefit of Korean Patent Application No. 10-2012-0089963, filed on Aug. 17, 2012, entitled “Semiconductor Device and Method for Manufacturing the Same”, which is hereby incorporated by reference in its entirety into this application.

### BACKGROUND OF THE INVENTION

1. Technical Field

The present invention relates to a semiconductor device and a method for manufacturing the same.

2. Description of the Related Art

The demand for inverters used in robots, air conditioners, machine tools, and the like, industrial electronics which are represented by an uninterrupted power supply for office machine, and small-sized power converters, is rapidly increasing. It has been gradually important in these power converters that the apparatus has a smaller size and a lighter weight, a higher efficiency, and a lower noise. However, these requests are difficult to simultaneously satisfy by only power semiconductor devices of the prior art, such as, a bipolar transistor, a high power MOS field effect transistor (MOSFET), or the like. Therefore, an insulated gate bipolar transistor (IGBT), which is a semiconductor device retaining both of high-speed switching characteristics of the high power MOSFET and high power characteristics of the bipolar transistor, has received attention. A trench structured IGBT has a structure where a plurality of trench grooves are formed to promote a high withstand voltage and a gate insulating film and a gate electrode are disposed within the trench (U.S. Pat. No. 5,801,408).

### SUMMARY OF THE INVENTION

The present invention has been made in an effort to provide a semiconductor device capable of reducing a mask manufacturing process, and a method for manufacturing the same.

The present invention has been made in an effort to provide a semiconductor device capable of reducing a semiconductor device manufacturing process, and a method for manufacturing the same. The present invention has been made in an effort to provide a semiconductor device capable of reducing time and costs, and a method for manufacturing the same.

According to one preferred embodiment of the present invention, there is provided a semiconductor device, including: a plurality of trench gate electrodes formed in a semiconductor substrate; a gate insulating film covering an upper surface of the semiconductor substrate and lateral surfaces and lower surfaces of the trench gate electrodes; a base region formed between the trench gate electrodes; an emitter region formed between the trench gate electrodes and on the base region; interlayer insulating films formed on the trench gate electrodes and spaced apart from each other; an emitter metal layer formed on the interlayer insulating films and between the interlayer insulating films, the emitter metal layer passing through the emitter region to be positioned within the base region; and a buffer region formed within the base region, the buffer region surrounding a portion of the emitter metal layer which is positioned within the base region.

The semiconductor substrate may be an N-type semiconductor substrate. The base region may be formed by injection of a low-concentration P-type impurity. The emitter region may be formed by injection of a high-concentration N-type impurity. The buffer region may be formed by injection of a high-concentration P-type impurity.

The gate insulating film may contain at least one of silicon oxide, SiON, GexOyNz, and a high-k material.

The trench gate electrode may be formed of poly-silicon. The interlayer insulating film may contain at least one of borophosphosilicate glass (BPSG) and tetraethylorthosilicate (TEOS).

Here, a lower surface of the buffer region may be spaced apart from a lower boundary surface of the base region.

According to another preferred embodiment of the present invention, there is provided a method for manufacturing a semiconductor device, the method including: preparing a semiconductor substrate; forming a plurality of trench gate electrodes in the semiconductor substrate; forming interlayer insulating films on the trench gate electrodes; forming a base region in the semiconductor substrate; forming an emitter region within the base region; forming an emitter metal layer trench which passes through the emitter region to be positioned within the base region; forming a buffer region formed within the base region, the buffer region surrounding a portion of the emitter metal layer trench which is formed within the base region; and forming an emitter metal layer in an inner portion of the emitter metal layer trench, on the emitter metal layer, and on the interlayer insulating films.

The semiconductor substrate may be an N-type semiconductor substrate. The forming of the plurality of trench gate electrodes may include: preparing a gate trench mask positioned above the semiconductor substrate, the gate trench mask opening regions of the semiconductor substrate where the trench gate electrodes are to be formed; forming gate trenches in the semiconductor substrate; forming a gate insulating film on the semiconductor substrate and in inner portions of the gate trenches; and filling the inner portions of the gate trenches with poly-silicon.

Here, in the forming of the gate insulating film, the gate insulating film may contain at least one of silicon oxide, SiON, GexOyNz, and a high-k material. The forming of the gate trenches may be performed by a photolithographic process.

The filling of the inner portions of the gate trenches with poly-silicon may include: forming poly-silicon in the inner portions of the gate trenches and on the gate trenches and the gate insulating film; and removing the poly-silicon on the gate trenches and the gate insulating film.

The removing of the poly-silicon may be performed by an etch-back process or a wet etching process.

Here, in the forming of the interlayer insulating films, the interlayer insulating film may contain at least one of borophosphosilicate glass (BPSG) and tetraethylorthosilicate (LOS).

The forming of the base region may be performed by injecting a low-concentration P-type impurity into the semiconductor substrate. The forming of the emitter region may be performed by injecting a high-concentration N-type impurity into the base region.

Here, in the forming of the emitter metal layer trench, the emitter metal layer trench may be formed in the semiconductor substrate between the interlayer insulating films.

The forming of the emitter metal layer trench may be performed by a photolithographic process. Here, in the forming of the emitter metal layer trench, the emitter metal layer trench may have such a depth that a lower portion of the buffer region is spaced apart from a lower boundary surface of the base region.

The forming of the buffer region may be performed by injecting a high-concentration P-type impurity into the base region. Here, in the forming of the buffer region, a lower portion of the buffer region may be spaced apart from a lower boundary surface of the base region.

### BRIEF DESCRIPTION OF THE DRAWINGS

The above and other objects, features, and advantages of the present invention will be more clearly understood from the following detailed description taken in conjunction with the accompanying drawings, in which:

FIG. 1 is an exemplified view showing a semiconductor device according to a preferred embodiment of the present invention; and

FIGS. 2 to 12 are exemplified views showing a method for manufacturing the semiconductor device according to the preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

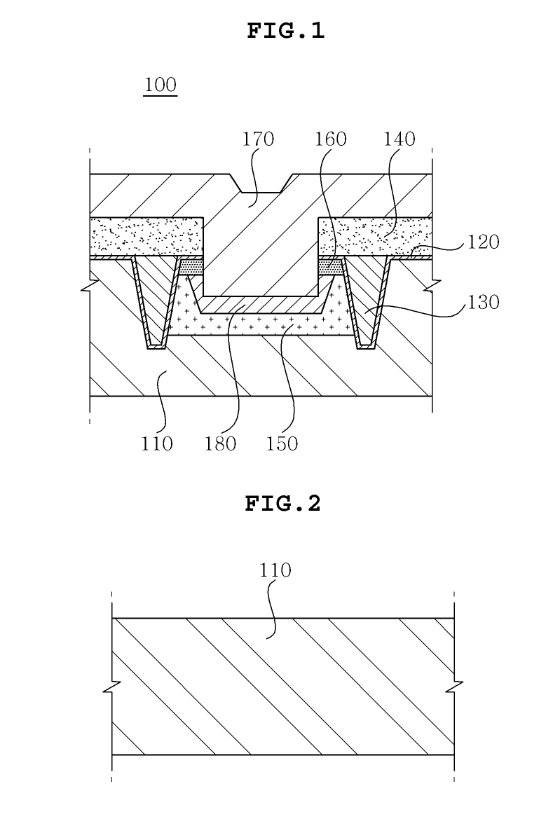

FIG. 1 is an exemplified view showing a semiconductor device according to a preferred embodiment of the present invention.

Referring to FIG. 1, a semiconductor device 100 may include a semiconductor substrate 110, trench gate electrodes 130, a gate insulating film 120, a base region 150, an emitter region 160, interlayer insulating films 140, an emitter metal layer 170, and a buffer region 180.

The semiconductor substrate 110 may be an N-type semiconductor substrate. That is, the semiconductor substrate 110 may be a semiconductor doped with an N-type impurity. Here, the N-type impurity may be a Group V element, such as, phosphorous (P), arsenic (As), or the like.

The trench gate electrodes 130 may be formed in the semiconductor substrate 110 in plural. In addition, the trench gate electrode 130 may be formed inside the semiconductor substrate 110. The trench gate electrode 130 may be formed of poly-silicon. The number of trench gate electrodes 130 is two in FIG. 1, but is not limited thereto. The number of trench gate electrodes 130 may be designed and changed by those skilled in the art.

The gate insulating film 120 may be formed to cover an upper surface of the semiconductor substrate 110 and lateral surfaces and lower surfaces of the trench gate electrodes 130. The gate insulating film 120 may be formed in order to electrically insulate the trench gate electrodes 130 from the semiconductor substrate 110. The gate insulating film 120 may be formed of silicon oxide, SiON,

GexOyNz, a high-k material, or a combination thereof, or may be a lamination film where these are sequentially laminated or the like. The high-k material may be HfO₂, ZrO₂, Al₂O₃, Ta₂O₅, a hafnium silicate, zirconium silicate, or a combination thereof.

The base region 150 may be formed between the trench gate electrodes 130. The base region 150 may be formed by injecting a low-concentration P-type impurity into a portion of the semiconductor substrate 110 between the trench gate electrodes 130. For example, the P-type impurity may be boron (B), boron fluoride (BF₂, BF₃), indium (In), or the like.

The emitter region 160 may be formed on the base region 150. The emitter region 160 may be formed by injecting a high-concentration N-type impurity into the base region 150. Here, the emitter region 160 may be formed adjacently to the upper surface of the semiconductor substrate 110, which is above the base region 150.

The respective interlayer insulating films 140 may be formed on the trench gate electrodes 130. The interlayer insulating films 140 respectively formed on the trench gate electrodes 130 may be spaced apart from each other. The interlayer insulating film 140 may be formed of borophosphosilicate Glass (BPSG). In addition, the interlayer insulating film 140 may be formed of tetraethylorthosilicate (TEOS).

The emitter metal layer 170 may be formed on the interlayer insulating films and between the interlayer insulating films. In addition, a lower portion of the emitter metal layer 170 may be positioned within the base region 150 while passing through the emitter region 160. That is, the lower portion of the emitter metal layer 170 may be positioned between a lower boundary surface of the emitter region 160 and a lower boundary surface of the base region 150. In addition, the lower portion of the emitter metal layer 170 may be positioned such that a lower surface of the buffer region 180 formed underneath the emitter metal layer 170 is spaced apart from the lower boundary surface of the base region 150. Therefore, the emitter metal layer 170 formed inside the semiconductor substrate 110 may have such a depth that the lower surface of the buffer region 180 can be spaced apart from the lower boundary surface of the base region 150. The emitter metal layer 170 may be formed of a conductive material such as tungsten or the like.

The buffer region 180 may surround the lower portion of the emitter metal layer 170 within the base region 150. In addition, the buffer region 180 may be spaced apart from the lower boundary surface of the base region 150. The buffer region 180 may be formed in order to prevent an electric field from concentrating at corners of a lower portion of the emitter metal layer 170 positioned within the base region 150. In addition, the buffer region 180 is positioned within the base region, so that the withstand voltage can be prevented from reducing.

FIGS. 2 to 12 are exemplified views showing a method for manufacturing the semiconductor device according to the preferred embodiment of the present invention. Referring to FIG. 2, a semiconductor substrate 110 is provided. The semiconductor substrate 110 may be an N-type semiconductor substrate. The N-type semiconductor substrate 110 may be a semiconductor substrate doped with an N-type impurity. Here, the N-type impurity may be a Group V element, such as, phosphorous (P), arsenic (As), or the like.

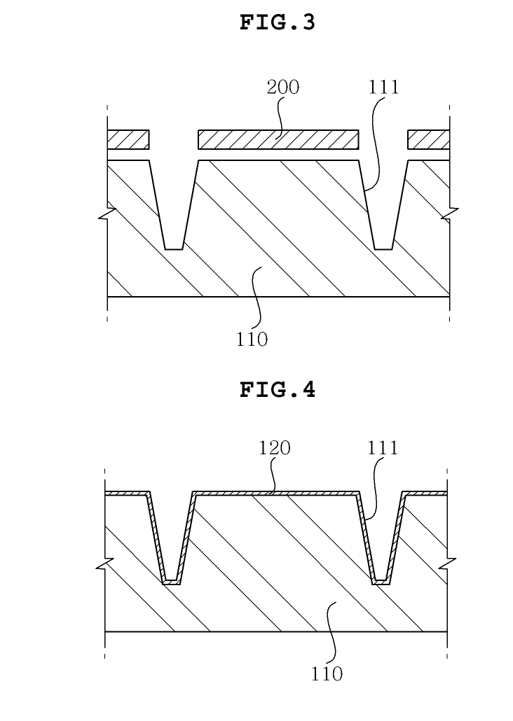

Referring to FIG. 3, gate trenches 111 may be formed in the semiconductor substrate 110. Firstly, a gate trench mask 200 may be positioned above the semiconductor substrate 110. The gate trench mask 200 is a mask for forming the gate trenches 111. The gate trench mask 200 may be patterned such that regions for the gate trenches 111 are opened. After the gate trench mask 200 is positioned above the semiconductor substrate 110, a photolithographic process is performed to form the gate trenches 111. After the gate trenches 111 are formed, the gate trench mask 200 may be removed. Two gate trenches 111 are formed in the present exemplary embodiment, but the present invention is not limited thereto. That is, the number of gate trenches 111 is not limited, and may be changed according to the need of those skilled in the art. In the present exemplary embodiment, the case where two gate trenches 111 are formed is exemplified, for convenience of explanation.

The gate trenches 111 may be formed before or after a base region 150 and an emitter region 160 are formed. However, when the gate trenches 111 are formed after the base region 150 and the emitter region 160 are formed, the impurity of the base region 150 may be out-diffused by a thermal process for forming a gate insulating film 120, which is to be subsequently performed. For this reason, the concentration of impurity in a channel region, which is turned on when a voltage is applied to a trench gate electrode 130, is lowered, resulting in raising the turn-on voltage. In order to prevent the turn-on voltage from being raised, the gate trenches 111 may be formed before the base region 150 and the emitter region 160 are formed in the present exemplary embodiment.

Referring to FIG. 4, a gate insulating film 120 may be formed. The gate insulating film 120 may be formed on the semiconductor substrate 110 and internal walls of the gate trenches 111. The gate insulating film 120 may be formed by using a chemical vapor deposition (CVD) process. For example, the gate insulating film 120 may be formed of silicon oxide film, SiON, GexOyNz, a high-k material, or a combination thereof, or may be a lamination film where these are sequentially laminated. The high-k material may be HfO₂, ZrO₂, Al₂O₃, Ta₂O₅, a hafnium silicate, zirconium silicate, or a combination thereof

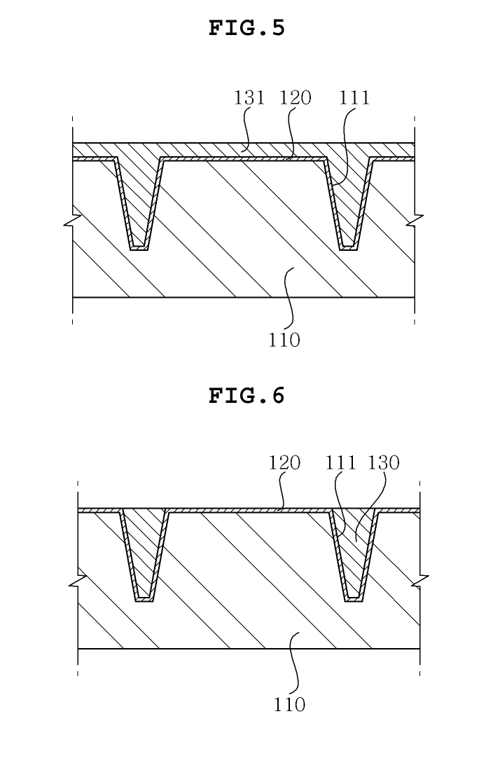

Referring to FIG. 5, a poly-silicon 131 may be formed on the gate insulating film 120. When the poly-silicon 131 is formed on the gate insulating film 120, inner portion of the gate trenches 111 may be filled with the poly-silicon 131. In addition, the poly-silicon 131 may be formed on the gate insulating film 120 and the gate trenches 111 to have a predetermined thickness.

Referring to FIG. 6, trench gate electrodes 130 may be formed. A portion of the poly-silicon 131, which is formed on the gate insulating film 120 and the gate trenches 111, may be removed. That is, the rest of the poly-silicon 131 except for a portion of the poly-silicon 131 filling the gate trenches 111 may be removed. A portion of the poly-silicon 131, which fills the inner portions of the gate trenches 111, may be the trench gate electrodes 130. The removal of the poly-silicon 131 may be performed by an etch-back or wet etching process. When the number of gate trenches 111 formed is plural, the trench gate electrodes 131 are also formed in plural.

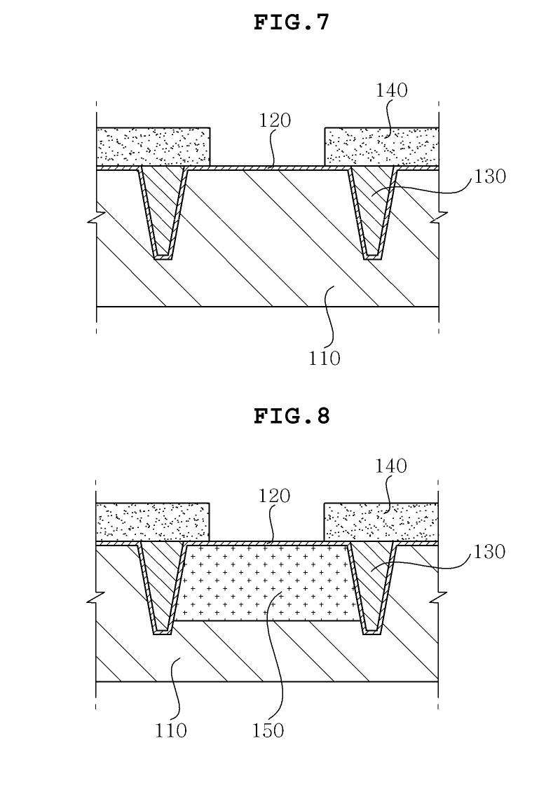

Referring to FIG. 7, interlayer insulating films 140 may be formed. The interlayer insulating films 140 may be formed on the trench gate electrodes 130, respectively. As the number of trench gate electrodes 130 formed is plural, the interlayer insulating films 140 are also formed in plural. The interlayer insulating films 140 respectively formed on the trench gate electrodes 130 may be spaced apart from each other. Meanwhile, the interlayer insulating film 140 may be formed of borophosphosilicate Glass (BPSG). Alternatively, the interlayer insulating film 140 may be formed of tetraethylorthosilicate (TEOS). Referring to FIG. 8, a base region 150 may be formed. The base region 150 may be formed by injecting a low-concentration P-type impurity into the semiconductor substrate 110. For example, the P-type impurity may be boron (B), boron fluoride (BF₂, BF₃), indium (In), or the like.

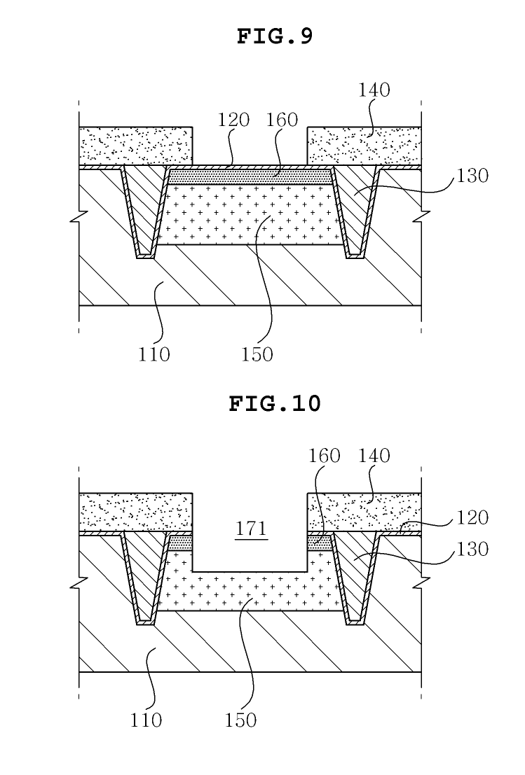

Referring to FIG. 9, an emitter region 160 may be formed. The emitter region 160 may be formed by injecting a high-concentration N-type impurity into the base region 150. Here, the emitter region 160 may be formed adjacently to the upper surface of the semiconductor substrate 110, which is above the base region 150.

Referring to FIG. 10, an emitter metal layer trench 171 may be formed. The emitter metal layer trench 171 may be formed by using the interlayer insulating films 140 as a mask. That is, the emitter metal layer trench 171 may be formed between the interlayer insulating films 140. The emitter metal layer trench 171 may be formed up to the base region 150 while passing through the emitter region 160. Here, a lower portion of the emitter metal layer trench 171 positioned within the base region 150 may be spaced apart from a lower boundary surface of the base region 150. In addition, the emitter metal layer trench 171 may be determined to have such a depth that a lower surface of a buffer region 180 to be formed later is spaced apart from the lower boundary surface of the base region 150. Here, the emitter region 160 may be separated into two parts by the emitter metal layer trench 171. Therefore, a mask used to separate the emitter region 160 into the two parts at the time of forming the emitter region 160 in the prior art may be omitted.

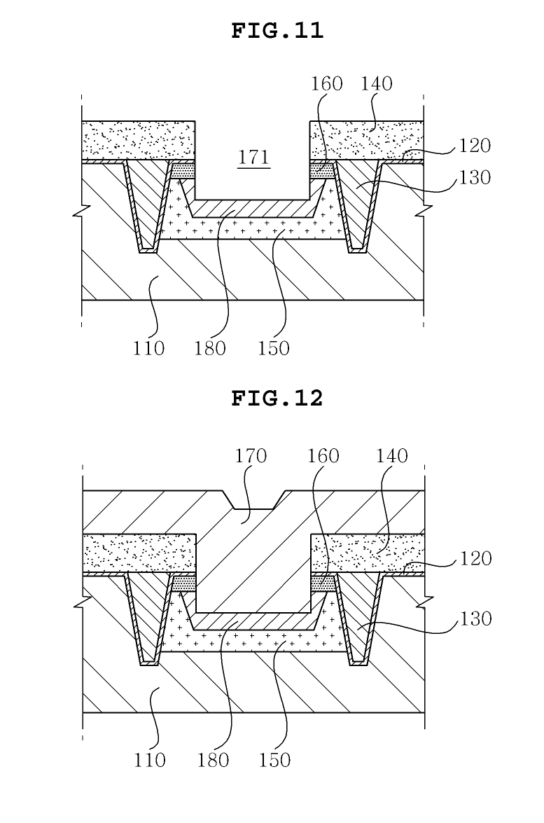

Referring to FIG. 11, a buffer region 180 may be formed. The buffer region 180 may be formed by injecting a high-concentration P-type impurity into the base region 150. Here, the high-concentration P-type impurity may be injected through the emitter metal layer trench 171. Therefore, the buffer region 180 may be formed within the base region 150. In addition, the buffer region 180 may surround the emitter metal layer trench 171 positioned within the base region 150. In addition, the buffer region 180 may be spaced apart from the lower boundary surface of the base region 150. A mask used for forming the buffer region 180 in the prior art may be omitted by using the emitter metal trench 171 at the time of forming the buffer region 180.

The buffer region 180 may be formed in order to prevent an electric field from concentrating at corners of a lower portion of the emitter metal layer 170 positioned within the base region 150. In addition, the buffer region 180 is positioned within the base region 150, so that the withstand voltage can be prevented from reducing. Referring to FIG. 12, an emitter metal layer 170 may be formed. The emitter metal layer 170 may be formed such that the emitter metal layer 170 covers an upper portion of the interlayer insulating film 140 and fills an inner portion of the emitter metal layer trenches 171. The emitter metal layer 170 may be formed of a conductive material such as tungsten or the like.

The present invention exemplifies the IGBT device as above, but the semiconductor devices to which the exemplary embodiment of the present invention is applied are not limited to the IGBT device. That is, the exemplary embodiment of the present invention may be applied to semiconductor devices such as an N-channel MOSFET or a P-channel MOSFET.

As set forth above, according to the semiconductor device and the method for manufacturing the same of the present invention, the mask for forming an emitter region and a butter region can be omitted by using the emitter metal layer trench. In addition, according to the semiconductor device and the method for manufacturing the same of the present invention, the mask for forming the emitter metal layer trench can be omitted by using an interlayer insulating film. That is, according to the semiconductor device and the method for manufacturing the same of the present invention, the number of semiconductor device manufacturing processes can be decreased by omitting the mask process. Hence, the semiconductor device manufacturing time and cost can be reduced.

As set forth above, according to the semiconductor device and the method for manufacturing the same of the present invention, the mask for forming an emitter region and a butter region can be omitted by using the emitter metal layer trench.

According to the semiconductor device and the method for manufacturing the same of the present invention, the mask for forming the emitter metal layer trench can be omitted by using an interlayer insulating film.

According to the semiconductor device and the method for manufacturing the same of the present invention, the time and costs can be reduced by omitting the mask manufacturing process.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A semiconductor device, comprising:
a plurality of trench gate electrodes formed in a semiconductor substrate;
a gate insulating film covering an upper surface of the semiconductor substrate and lateral surfaces and lower surfaces of the trench gate electrodes;
a base region formed between the trench gate electrodes;
an emitter region formed between the trench gate electrodes and on the base region;
interlayer insulating films formed on the trench gate electrodes and spaced apart from each other;
an emitter metal layer formed on the interlayer insulating films and between the interlayer insulating films, the emitter metal layer passing through the emitter region to be positioned within the base region; and
a buffer region formed within the base region, the buffer region surrounding a portion of the emitter metal layer which is positioned within the base region.

2. The semiconductor device as set forth in claim 1, wherein the semiconductor substrate is an N-type semiconductor substrate.

3. The semiconductor device as set forth in claim 1, wherein the base region is formed by injection of a low-concentration P-type impurity.

4. The semiconductor device as set forth in claim 1, wherein the emitter region is formed by injection of a high-concentration N-type impurity.

5. The semiconductor device as set forth in claim 1, wherein the buffer region is formed by injection of a high-concentration P-type impurity.

6. The semiconductor device as set forth in claim 1, wherein the gate insulating film contains at least one of silicon oxide, SiON, GexOyNz, and a high-k material.

7. The semiconductor device as set forth in claim 1, wherein the trench gate electrode is formed of poly-silicon.

8. The semiconductor device as set forth in claim 1, wherein the interlayer insulating film contains at least one of borophosphosilicate glass (BPSG) and tetraethylorthosilicate (TEOS).

9. The semiconductor device as set forth in claim 1, wherein a lower surface of the buffer region is spaced apart from a lower boundary surface of the base region.

10. A method for manufacturing a semiconductor device, the method comprising:
preparing a semiconductor substrate;
forming a plurality of trench gate electrodes in the semiconductor substrate;
forming interlayer insulating films on the trench gate electrodes;
forming a base region in the semiconductor substrate;
forming an emitter region within the base region;
forming an emitter metal layer trench which passes through the emitter region to be positioned within the base region;
forming a buffer region formed within the base region, the buffer region surrounding a portion of the emitter metal layer trench which is formed within the base region; and
forming an emitter metal layer in an inner portion of the emitter metal layer trench, on the emitter metal layer, and on the interlayer insulating films.

11. The method as set forth in claim 10, wherein the semiconductor substrate is an N-type semiconductor substrate.

12. The method as set forth in claim 10, wherein the forming of the plurality of trench gate electrodes includes:
preparing a gate trench mask positioned above the semiconductor substrate, the gate trench mask opening regions of the semiconductor substrate where the trench gate electrodes are to be formed;
forming gate trenches in the semiconductor substrate;
forming a gate insulating film on the semiconductor substrate and in inner portions of the gate trenches; and
filling poly-silicon in the inner portions of the gate trenches.

13. The method as set forth in claim 12, wherein in the forming of the gate insulating film, the gate insulating film contains at least one of silicon oxide, SiON, GexOyNz, and a high-k material.

14. The method as set forth in claim 12, wherein the forming of the gate trenches is performed by a photolithographic process.

15. The method as set forth in claim 12, wherein the filling of the inner portions of the gate trenches with poly-silicon includes:
forming poly-silicon in the inner portions of the gate trenches and on the gate trenches and the gate insulating film; and
removing the poly-silicon on the gate trenches and the gate insulating film.

16. The method as set forth in claim 15, wherein the removing of the poly-silicon is performed by an etch-back process or a wet etching process.

17. The method as set forth in claim 10, wherein in the forming of the interlayer insulating films, the interlayer insulating film contains at least one of borophosphosilicate glass (BPSG) and tetraethylorthosilicate (MOS).

18. The method as set forth in claim 10, wherein the forming of the base region is performed by injecting a low-concentration P-type impurity into the semiconductor substrate.

19. The method as set forth in claim 10, wherein the forming of the emitter region is performed by injecting a high-concentration N-type impurity into the base region.

20. The method as set forth in claim 10, wherein in the forming of the emitter metal layer trench, the emitter metal layer trench is formed in the semiconductor substrate between the interlayer insulating films.

21. The method as set forth in claim 10, wherein the forming of the emitter metal layer trench is performed by a photolithographic process.

22. The method as set forth in claim 10, wherein in the forming of the emitter metal layer trench, the emitter metal layer trench has such a depth that a lower portion of the buffer region is spaced apart from a lower boundary surface of the base region.

23. The method as set forth in claim 10, wherein the forming of the buffer region is performed by injecting a high-concentration P-type impurity into the base region.

24. The method as set forth in claim 10, wherein in the forming of the buffer region, a lower portion of the buffer region is spaced apart from a lower boundary surface of the base region.
